(19) United States
(12) Patent Application Publication
(10) Pub. No.: US 2026/0353900 A1
(43) Pub. Date: Nov. 5, 2026

(54) DISPLAY DEVICE AND DISPLAY SYSTEM

(71) Applicant: SAMSUNG ELECTRONICS CO., LTD., Suwon-si (KR)

(72) Inventors: Dohoon KIM, Yokohama-shi (JP); Dai AOKI, Yokohama-shi (JP); Atsushi SATO, Yokohama-shi (JP)

(73) Assignee: SAMSUNG ELECTRONICS CO., LTD., Suwon-si (KR)

(21) Appl. No.: 19/719,858

(22) Filed: Jun. 25, 2026

Related U.S. Application Data
(63) Continuation of application No. PCT/KR2025/000252, filed on Jan. 6, 2025.

(30) Foreign Application Priority Data
Jan. 24, 2024 (JP) 2024-008634

(51) Int. Cl. H10H 29/856

(52) U.S. Cl. CPC H10H 29/856

(57) ABSTRACT

A display device includes: a plurality of light emitting elements on a circuit board and spaced apart from each other, the plurality of light emitting elements configured to emit light forward, respectively; a reflective layer on a transparent substrate facing the circuit board, the reflective layer including openings at positions corresponding to the plurality of light emitting elements such that light emitted from the plurality of light emitting elements respectively passes through corresponding openings and is emitted forward, the reflective layer being configured to reflect light from the front; and a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively.

### CROSS-REFERENCE TO RELATED APPLICATION(S)

This application is a continuation of International Application No. PCT/KR2025/000252, filed on Jan. 6, 2025, in the Korean Intellectual Property Receiving Office, which is based on and claims priority to Japanese Patent Application No. 2024-008634, filed on Jan. 24, 2024, in the Japan Patent Office, the disclosures of which are incorporated by reference herein in their entireties.

### BACKGROUND

### 1. Field

The present disclosure relates to a display device and a display system.

### 2. Description of Related Art

In a related art, a mirror display may include both a mirror function of reflecting light and illuminating surrounding objects.

The mirror display may be an organic light emitting display device provided with a first substrate having a plurality of organic light emitting elements, and a second substrate having a reflective layer in which a plurality of openings are formed at positions corresponding to the plurality of organic light emitting elements. The organic light emitting display device may realize the mirror function by the reflective layer reflecting light, and may realize the display function by emitting light emitted from the organic light emitting element to the outside through the opening. Further, a mirror function with high reflectivity may be realized by the reflective layer, and a display function with high display luminance may be realized without losing light through the opening.

A display device having both the display function and the mirror function may require higher display luminance and higher reflectivity. Accordingly, recently, applying small and high-luminance light emitting elements such as a micro light emitting diode (LED) is being considered. Since the micro LED is an inorganic LED, high display luminance may be realized, and since a chip size is small, high reflectivity may be realized by minimizing the opening of the reflective layer. The plurality of micro LEDs constituting each pixel of the display device may be disposed close to each other.

However, when a distance between micro LEDs adjacent to each other is close, light emitted from a specific micro LED may be emitted to the outside through an opening other than the corresponding opening, thereby causing deterioration in image quality of a display image.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

Provided is a display device capable of displaying a high-quality image even when using a small and high-luminance light emitting element to realize higher display luminance and higher reflectivity in a display device having both the display function and the mirror function.

Further, provided is a display system including a plurality of the display devices.

Additional aspects will be set forth in part in the description which follows and, in part, will be apparent from the description, or may be learned by practice of the presented embodiments.

According to an aspect of the disclosure, a display device may include: a plurality of light emitting elements on a circuit board and spaced apart from each other, the plurality of light emitting elements configured to emit light forward, respectively; a reflective layer on a transparent substrate facing the circuit board, the reflective layer including openings at positions corresponding to the plurality of light emitting elements such that light emitted from the plurality of light emitting elements respectively passes through corresponding openings and is emitted forward, the reflective layer being configured to reflect light from the front; and a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively.

According to an aspect of the disclosure, a display system may include a plurality of the display devices, each including: a plurality of light emitting elements on a circuit board and spaced apart from each other, the plurality of light emitting elements configured to emit light forward, respectively; a reflective layer on a transparent substrate facing the circuit board, the reflective layer including openings at positions corresponding to the plurality of light emitting elements such that light emitted from the plurality of light emitting elements respectively passes through corresponding openings and is emitted forward, the reflective layer being configured to reflect light from the front; and a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively. The plurality of the display devices may be in a tile shape.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a plan view illustrating a schematic configuration of a display device according to an embodiment of the present disclosure;

FIG. 2 is a cross-sectional view taken along line II-II′ of FIG. 1 according to an embodiment of the present disclosure;

FIG. 3A is a view illustrating an optical path in the display device according to an embodiment of the present disclosure;

FIG. 3B is a view illustrating an optical path in a related display device as a comparative example;

FIG. 4A is a view illustrating an optical path when the transparent substrate is thin according to an embodiment of the present disclosure;

FIG. 4B is a view illustrating an optical path when the transparent substrate is thick according to an embodiment of the present disclosure;

FIG. 5A is a view illustrating a method for manufacturing the display device according to an embodiment of the present disclosure;

FIG. 5B is a view subsequent to FIG. 5A according to an embodiment of the present disclosure;

FIG. 5C is a view subsequent to FIG. 5B according to an embodiment of the present disclosure;

FIG. 5D is a view subsequent to FIG. 5C according to an embodiment of the present disclosure;

FIG. 5E is a view subsequent to FIG. 5D according to an embodiment of the present disclosure;

FIG. 5F is a view subsequent to FIG. 5E according to an embodiment of the present disclosure;

FIG. 6 is a cross-sectional view illustrating a schematic configuration of a display device according to a modified example according to an embodiment of the present disclosure;

FIG. 7 is a cross-sectional view illustrating a schematic configuration of a display device according an embodiment of the present disclosure;

FIG. 8 is a view illustrating a schematic configuration of a display device according to an embodiment of the present disclosure; and

FIG. 9 is a view illustrating a schematic configuration of a display system according to an embodiment of the present disclosure.

### DETAILED DESCRIPTION

Hereinafter, embodiments of the present disclosure are described in detail with reference to the drawings. In the drawings, the same reference numerals refer to the same components, and the size of each component in the drawings may be exaggerated for clarity and convenience of description. The embodiments described herein are non-limiting example embodiments, and thus, the disclosure is not limited thereto and may be realized in various other forms. One or more features of at least one embodiment provided herein may be applied to one or more other embodiments provided herein or not provided but consistent with the disclosure. Also, at least one embodiment provided herein is not excluded from being associated with one or more features of another example or another embodiment also provided herein or not provided herein but consistent with the disclosure. Meanwhile, the embodiments described below are merely exemplary, and various modifications may be made thereto.

Hereinafter, what is described as “upper part” or “upper” may include not only what is directly above in contact, but also what is above without contact. Similarly, what is described as “lower part” or “lower” may include not only what is directly below in contact, but also what is below without contact.

A singular expression includes a plural expression unless the context clearly indicates the singular. Further, when a specific part is said to “include”, “have” or “comprise” a specific component (or variations of “include,” “have” or “comprise”), this means that other components may be further included rather than excluding other components, unless specifically stated to the contrary.

Unless an order is explicitly stated for steps constituting a method, or there is a contrary description, the steps are performed in an appropriate order. The order of description of the steps is not necessarily limited. The use of all examples or exemplary terms is merely for describing the technical spirit, and the scope is not limited by the examples or exemplary terms unless limited by the claims.

### First Embodiment

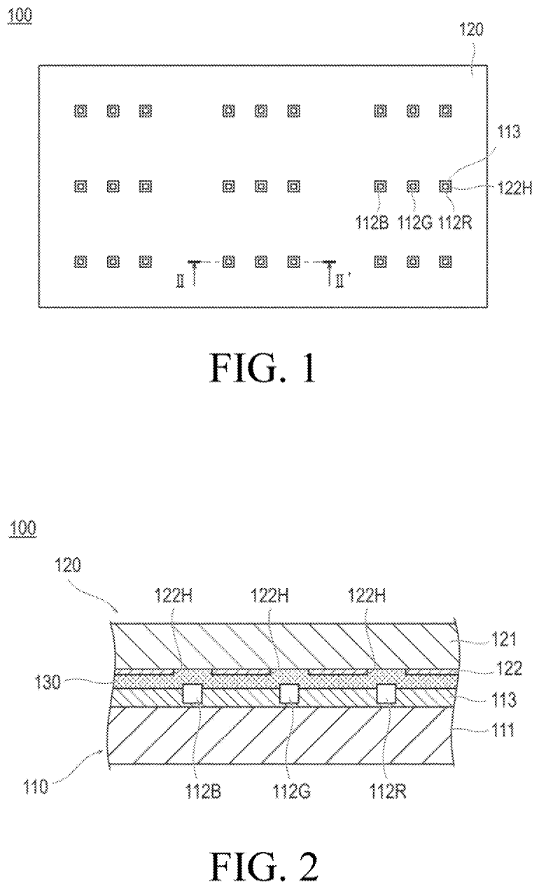

Hereinafter, a display device 100 according to a first embodiment of the present disclosure is described with reference to FIGS. 1 to 5. The display device 100 according to the present embodiment is a mirror display having both a display function of emitting light to display a desired image and a mirror function of reflecting light to illuminate surrounding objects.

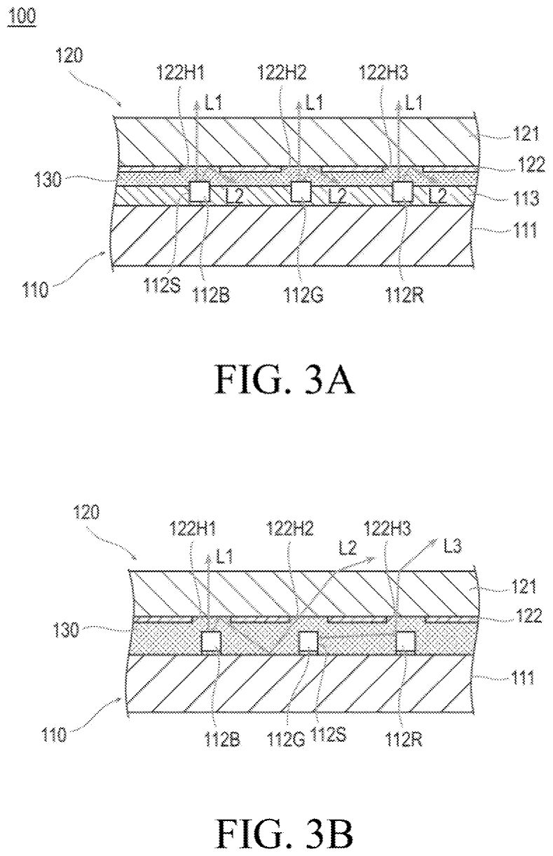

FIG. 1 is a plan view illustrating a schematic configuration of the display device 100 according to the first embodiment of the present disclosure. FIG. 2 is a cross-sectional view taken along line II-II′ of FIG. 1.

As illustrated in FIGS. 1 and 2, the display device 100 according to an embodiment of the present disclosure may include a display substrate 110 in which a plurality of light emitting elements 112G, 112B, 112R (hereinafter, also collectively referred to as “light emitting element 112”) are disposed in an array shape, and a reflective substrate 120 in which a plurality of openings 122H exposing the plurality of light emitting elements 112G, 112B, 112R to the outside are formed. The display substrate 110 and the reflective substrate 120 may be bonded to each other through a transparent adhesive layer 130.

### <Display Substrate 110>

The display substrate 110 may be configured by mounting a plurality of light emitting elements 112 on a circuit board 111. Further, a light blocking layer 113 for absorbing a portion of light emitted from the light emitting element 112 may be formed in an area other than the area where the light emitting element 112 is disposed on the circuit board 111.

The circuit board 111 may be a thin film transistor (TFT) substrate on which a TFT, a line layer, etc. controlling an operation of the plurality of light emitting elements 112 are formed.

The light emitting element 112 includes a blue light emitting element 112B emitting blue light, a green light emitting element 112G emitting green light, and a red light emitting element 112R emitting red light, and may display a color image. The light emitting elements 112B, 112G, 112R may be micro LEDs having a chip size of 100μm square or less. Three light emitting elements 112B, 112G, 112R adjacent to each other may constitute one pixel. The three light emitting elements 112B, 112G, 112R may be disposed adjacent to each other at an interval smaller than a pixel size and a pixel pitch.

The light blocking layer 113 may be composed of a black anisotropic conductive film (ACF). The light blocking layer 113 may absorb light emitted from the light emitting element 112 while mechanically and electrically connecting the circuit board 111 and the light emitting element 112. The light emitting element 112 may be formed to be embedded in the light blocking layer 113, and the light blocking layer 113 may be configured to cover a side surface of the light emitting element 112.

### <Reflective Substrate 120>

The reflective substrate 120 may include a transparent substrate 121 and a reflective layer 122. Further, the reflective layer 122 may be formed on one surface of the transparent substrate 121. The transparent substrate 121 may be a transparent glass substrate, and the reflective layer 122 may be composed of an alloy of aluminum and niobium. The reflective layer 122 may function as a mirror surface reflecting light from the front of the display device 100 to illuminate surrounding objects. Meanwhile, a plurality of openings 122H are formed in the reflective layer 122 at positions corresponding to the light emitting elements 112, and the opening 122H may be configured to emit light emitted from the light emitting element 112 forward. The opening 122H may have a rectangular shape and, when viewed from above, the size of the opening 122H may be configured to be slightly larger than the chip size of the light emitting element 112. Further, when viewed from above, the light emitting element 112 may be configured to overlap the opening 122H.

Further, a thin glass substrate having a thickness of about 100 μm may be used as the transparent substrate 121. A detailed description of the thickness of the transparent substrate 121 is described below.

### <Transparent Adhesive Layer 130>

The transparent adhesive layer 130 is disposed between the display substrate 110 and the reflective substrate 120, and may bond the display substrate 110 and the reflective substrate 120 to each other. The transparent adhesive layer 130 may be an optical clear resin (OCR).

The display device 100 according to an embodiment of the present disclosure configured as described above, light emitted from the light emitting element 112 is emitted forward through the opening 122H, thereby providing a display function of displaying a desired image. On the other hand, light incident from the front is reflected by the reflective layer 122 of the reflective substrate 120, thereby implementing a mirror function of illuminating surrounding objects.

More specifically, since high-luminance light emitted from the light emitting element 112 is emitted to the outside through the opening 122H, there is no attenuation of light, and a display function with high display luminance may be provided. On the other hand, using the small light emitting element 112, the size of the opening 122H is minimized, and the area of the reflective layer 122 is maximized, thereby providing a mirror function with high reflectivity. Further, since the light blocking layer 113 absorbing a portion of light emitted from the light emitting element 112 is formed, a portion of light emitted from the light emitting element 112 is prevented from being emitted forward through another opening 122H other than the corresponding opening 122H, thereby enhancing the image quality of the display image.

Further, the area ratio of the opening 122H on the surface of the reflective substrate 120 may be 10%, and the area ratio of the reflective layer 122 may be 90%. According to an embodiment, a display device having mirror performance with reflectivity of 83% or more defined in the Japanese Industrial Standards (JIS) may be provided.

### <Display Operation of Display Device 100>

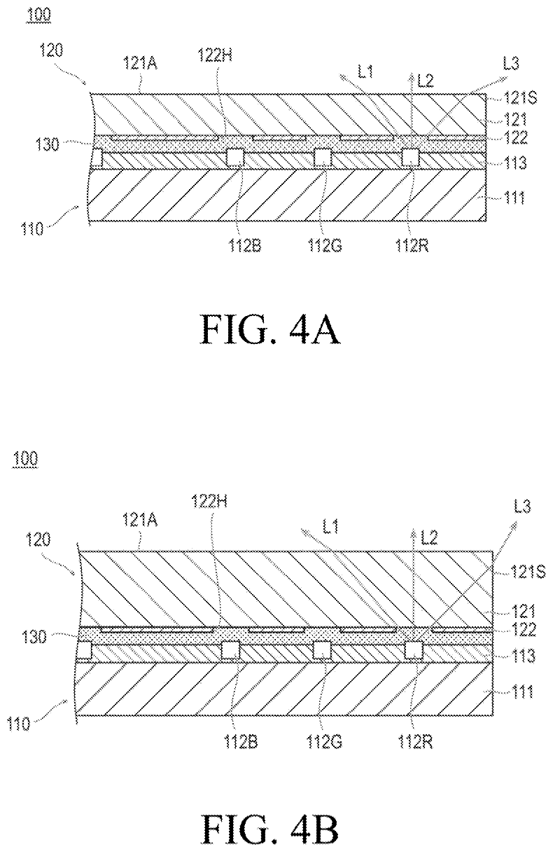

A display operation of the display device 100 is described in detail with reference to FIGS. 3A and 3B. FIG. 3A is a view illustrating an optical path in the display device 100, and FIG. 3B is a view illustrating an optical path in a display device according to a comparative example not provided with the light blocking layer.

As illustrated in FIG. 3B, in the display device according to the comparative example, e.g., light L1 emitted forward from a front surface of the light emitting element 112B is incident on the transparent substrate 121 through the corresponding opening 122H1 located in front of the light emitting element 112B, and is emitted to the outside. On the other hand, a portion of light L2 emitted from the front surface of the light emitting element 112B is reflected at a surface of the transparent substrate 121 and then reflected in the display device 100, and is emitted to the outside through another opening 122H2 other than the corresponding opening 122H1. Further, light L3 emitted from a side surface 112S of the light emitting element 112G is also emitted to the outside through another opening 122H3 other than the corresponding opening 122H2.

Therefore, in the example display device not provided with the light blocking layer, crosstalk of light occurs, and deterioration in image quality (such as change in color) of the display image may occur.

On the other hand, as illustrated in FIG. 3A, the display device 100 according to an embodiment of the present disclosure, light L2 emitted from the light emitting element 112 and reflected at the surface of the transparent substrate 121 is absorbed by the light blocking layer 113, so that the light L2 may not be emitted to the outside through another opening 122H. Further, the display device 100 according to an embodiment of the present disclosure, since the side surface 112S of the light emitting element 112 is covered with the light blocking layer 113, light emitted from the side surface 112S of the light emitting element 112 may also not be emitted to the outside through another opening 122H.

Therefore, according to the display device 100 of the present embodiment, crosstalk of light does not occur, and a high-quality image may be displayed.

### <Thickness of Transparent Substrate 121>

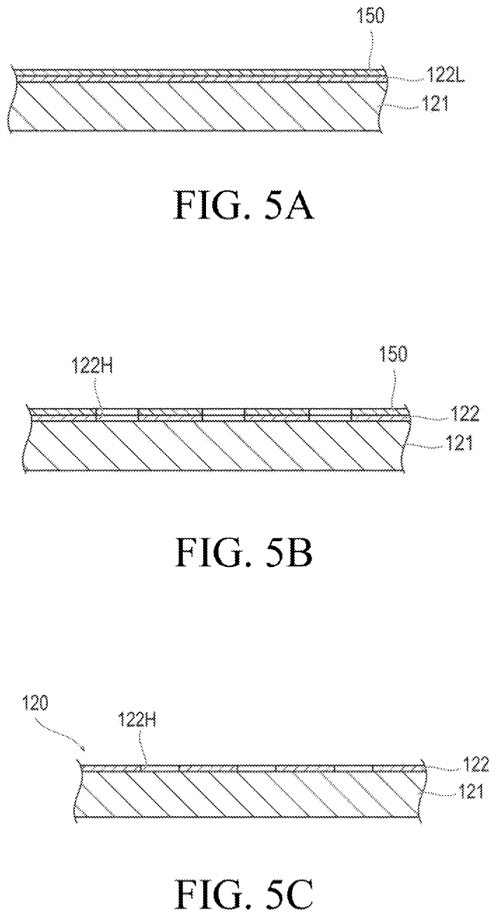

Next, the thickness of the transparent substrate 121 of the display device 100 is described in detail with reference to FIGS. 4A and 4B. As described above, in the display device 100 of the present embodiment, a thin glass substrate having a thickness of about 100 μm is used as the transparent substrate 121.

FIG. 4A is a view illustrating an optical path when the transparent substrate 121 is thin, and FIG. 4B is a view illustrating an optical path when the transparent substrate 121 is thick.

As illustrated in FIG. 4B, when the transparent substrate 121 is thick, a portion of light L3 among light L1, L2, L3 emitted from the light emitting element 112R installed at an end of the display substrate 110 may reach two opposite ends 121S in a direction in which the transparent substrate 121 extends after passing through the opening 122H. The light L3 reaching two opposite ends 121S in the direction in which the transparent substrate 121 extends may generate linear light (White Seam) at a corner portion of the display device 100, e.g., when connecting a plurality of display devices 100, which may be undesirable in some instances.

On the other hand, as illustrated in FIG. 4A, when the transparent substrate 121 is thin, light L1, L2, L3 emitted from the light emitting element 112R installed at the end of the display substrate 110 is emitted to the outside from a front surface 121A of the transparent substrate 121 after passing through the opening 122H without reaching two opposite ends 121S in the direction in which the transparent substrate 121 extends. Therefore, according to the display device 100 using the thin glass substrate, when connecting a plurality of display devices 100, linear light does not occur at the corner portion of the display device 100, and the image quality of the display image is enhanced.

As described above, in the display device 100 of the present embodiment, the thickness of the transparent substrate 121 is preset so that light emitted from the light emitting element 112 located at the end of the circuit board 111 does not reach two opposite ends 121S in the direction in which the transparent substrate 121 extends.

<Method for manufacturing display device 100>

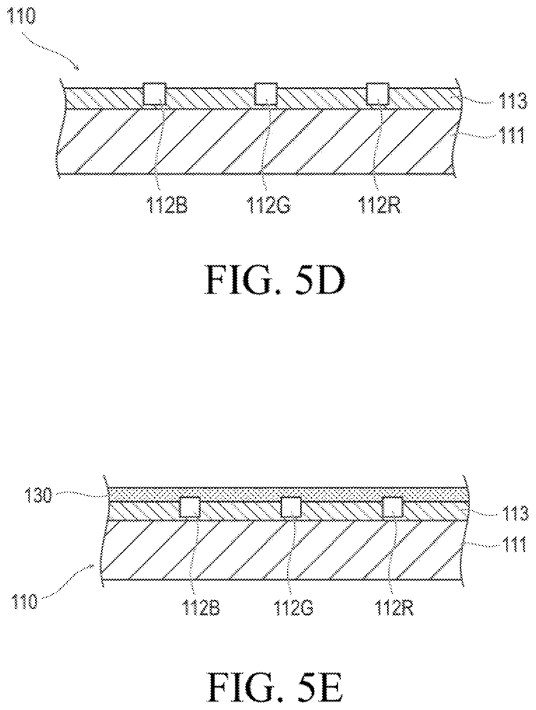

Next, a method for manufacturing the display device 100 is described with reference to FIGS. 5A to 5F.

First, a metal film 122L formed of an alloy of aluminum and niobium is formed on the transparent substrate 121, and a photoresist 150 is applied on the metal film 122L (see FIG. 5A). Subsequently, an opening 112H is formed in the metal film 122L using a photolithography process (see FIG. 5B). Thereafter, the reflective substrate 120 is completed by removing the photoresist 150 (see FIG. 5C).

Subsequently, the light blocking layer 113, which is a black anisotropic conductive film, is formed on the circuit board 111, and the light emitting element 112 is embedded in the anisotropic conductive film, thereby completing the display substrate 110 provided with the light emitting element 112 and the light blocking layer 113 (see FIG. 5D).

Subsequently, the transparent adhesive layer 130 is applied on the display substrate 110 (see FIG. 5E). Then, the reflective substrate 120 is bonded to the transparent adhesive layer 130 on the display substrate 110 such that the reflective layer 122 of the transparent substrate 121 faces the display substrate 110, thereby completing the display device 100 (see FIG. 5F).

Further, the material of each member of the display device 100 is not limited to the material, and various materials may be used. For example, the transparent substrate 121 may be a transparent resin substrate, and the reflective layer 122 may be composed of an arbitrary metal such as silver, aluminum, a silver alloy, and an aluminum alloy. Further, the light blocking layer 113 is not limited to the black anisotropic conductive film, and may be composed of a black matrix material or the like. When the light blocking layer is a black matrix material, the light emitting element 112 may be mounted on the circuit board 111 by a bonding technique such as soldering. Further, the color of the light blocking layer 113 is not limited to black, and an arbitrary color capable of absorbing light may be used.

### Modified Example

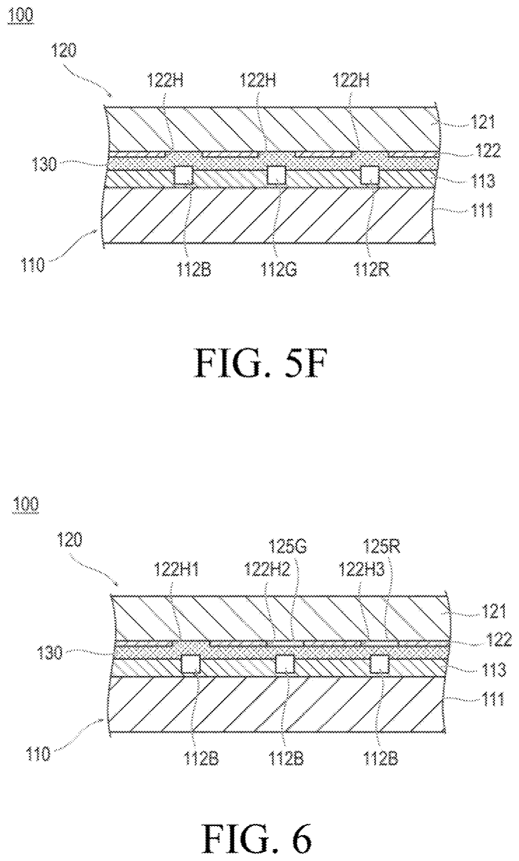

Next, a modified example of the display device 100 according to the present embodiment is described with reference to FIG. 6.

FIG. 6 is a cross-sectional view illustrating a schematic configuration of the display device 100 according to the modified example. The display device according to the modified example differs from the display device according to the first embodiment in that color display is realized using a color conversion layer. Further, the same reference numerals are given to the same configurations as those of the first embodiment, and the description thereof is omitted.

The display device 100 according to the modified example may include a display substrate 110 in which a plurality of light emitting elements 112B are disposed in an array shape, and a reflective substrate 120 in which a plurality of openings 122H corresponding to the plurality of light emitting elements 112B are formed. The display substrate 110 and the reflective substrate 120 may be bonded to each other through a transparent adhesive layer 130.

The display substrate 110 may have a plurality of blue light emitting elements 112B mounted on a circuit board 111. A light blocking layer 113 may be formed in an area other than the area where the blue light emitting element 112B is installed on the display substrate 110.

The reflective substrate 120 may have a reflective layer 122 in which openings 122H1, 122H2, 122H3 are formed at positions corresponding to the blue light emitting elements 112B. Color conversion layers 125G, 125R may be formed in two openings 122H2, 122H3 among three openings 122H1, 122H2, 122H3 corresponding to three blue light emitting elements 112B constituting one pixel. The color conversion layers 125G, 125R may include a green conversion layer 125G formed of a color conversion material converting blue light into green light, and a red conversion layer 125R formed of a color conversion material converting blue light into red light. The color conversion material includes a phosphor or a quantum dot.

According to the display device 100 configured as described above, a color image may be realized using only the blue light emitting element 112B. Further, since the light blocking layer 113 is formed on the circuit board 111, a portion of light emitted from a specific light emitting element 112B may not reach another opening 122H other than the corresponding opening 122H. More specifically, e.g., it may be configured such that light emitted from the blue light emitting element 112B corresponding to the opening 122H1 in which the color conversion layer is not formed is reflected at the surface of the transparent substrate 121 and does not enter the color conversion layers 125G, 125R formed in the other openings 122H2, 122H3.

Therefore, according to the display device 100 of the modified example, e.g., when displaying only a blue image, green light or red light is not mixed with blue light and emitted to the outside, so that a high-quality blue image may be displayed.

Further, the light emitting element according to the modified example is not limited to the blue light emitting element, and a light emitting element emitting light of a specific wavelength such as white light or ultraviolet light may be used. The color conversion material constituting the color conversion layer may be changed according to light emitted by the light emitting element.

### Second Embodiment

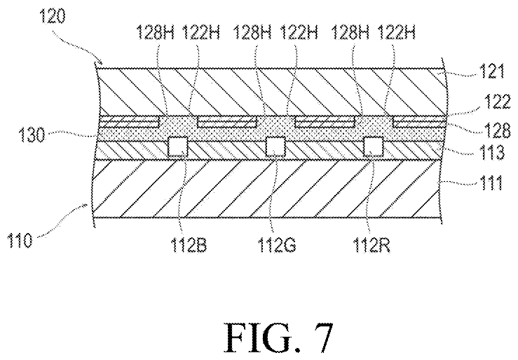

Next, a display device 100 according to a second embodiment of the present disclosure is described with reference to FIG. 7. The display device according to the second embodiment may differ from the display device according to the first embodiment in that a light blocking layer is additionally formed on a reflective substrate. Further, the same reference numerals are given to the same configurations as those of the first embodiment, and the description thereof is omitted.

The display device 100 according to the present embodiment may include a display substrate 110 in which a plurality of light emitting elements 112B, 112G, 112R are disposed in an array shape, and a reflective substrate 120 in which a plurality of openings 122H corresponding to the plurality of light emitting elements 112B, 112G, 112R are formed. The display substrate 110 and the reflective substrate 120 may be bonded to each other through a transparent adhesive layer 130.

The display substrate 110 may be configured to have a plurality of light emitting elements 112B, 112G, 112R mounted on a circuit board 111. The light emitting element 112 may be mounted on the circuit board 111 by a bonding technique such as soldering.

According to an embodiment, the reflective substrate 120 may further include a second light blocking layer 128.

The reflective substrate 120 has a reflective layer 122 in which an opening 122H is formed at a position corresponding to the light emitting element 112, and a second light blocking layer 128 may be further formed on the reflective layer 122. Similar to the reflective layer 122, an opening 128H is formed in the second light blocking layer 128 at a position corresponding to the light emitting element 112, and light emitted from the light emitting element 112 may be emitted to the outside through the openings 122H, 128H. The light blocking layer 128 is composed of, e.g., a black matrix material, and may absorb a portion of light emitted from the light emitting element 112.

According to the display device 100 configured as described above, a portion of light emitted from the light emitting element 112 is absorbed by the second light blocking layer 128 formed on the transparent substrate 121, and the portion of light may not be emitted to the outside from another opening 122H. Therefore, according to the display device 100 of the present embodiment, crosstalk of light does not occur, and a high-quality image may be displayed.

### Third Embodiment

In the first and second embodiments described above, the case where the display substrate 110 and the reflective substrate 120 have the same size has been described as an example. However, the sizes of the display substrate 110 and the reflective substrate 120 may be different.

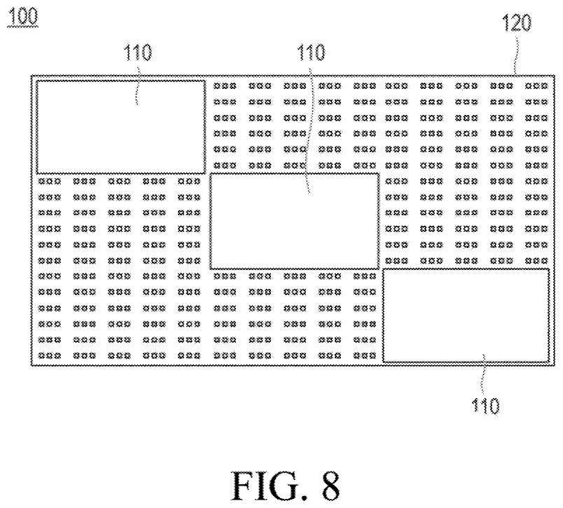

As illustrated in FIG. 8, in the display device 100 according to a third embodiment of the present disclosure, when viewed from above, the size of the reflective substrate 120 may be formed to be larger than the size of the display substrate 110. Further, when viewed from above, the display substrate 110 may be configured to overlap the reflective substrate 120. Further, a plurality of small display substrates 110 are bonded to the large reflective substrate 120.

According to an embodiment, it is possible to increase the size of the display device 100 without increasing the size of the display substrate 110.

### <Display System>

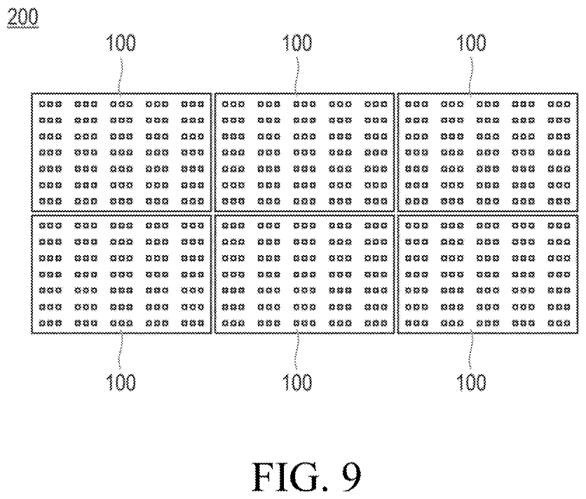

Finally, a display system 200 according to an embodiment of the present disclosure is described with reference to FIG. 9. The display system 200 according to the present embodiment includes a plurality of display devices 100.

As illustrated in FIG. 9, the display system 200 is configured by disposing the plurality of display devices 100 in a tile shape. The display substrate 110 and the reflective substrate 120 of the display device 100 have about the same size.

According to an embodiment, the degree of freedom in the shape of the display plane is enhanced, and for example, a large mirror display having an L-shaped display plane may be easily provided.

The present disclosure is not limited to the above-described embodiments, and various modifications may be made within the scope of the claims.

For example, in the above-described embodiment, the case where the size of the opening formed in the reflective layer is larger than the size of the front surface of the light emitting element has been described as an example. However, the size of the opening is not limited to being larger than the size of the front surface of the light emitting element. The size of the opening may be equal to the size of the front surface of the light emitting element, or may be smaller than the size of the front surface of the light emitting element. Further, the shape of the opening is not particularly limited, and is appropriately changed according to the shape of the front surface of the light emitting element.

Further, in the embodiment, the case where the light emitting element is an inorganic light emitting element (micro LED) has been described as an example. However, the light emitting element is not limited to the inorganic light emitting element, and various light emitting elements such as an organic light emitting element may be applied.

Further, in the above-described embodiment, the reflective layer was formed on a surface (rear surface) of the transparent substrate on a side facing the display substrate. However, the reflective layer may be formed on a surface (front surface) of the transparent substrate on an opposite side from the display substrate. In this case, it may be desirable to form an anti-oxidation film on the reflective layer.

According to an aspect of the disclosure, a display device may include: a plurality of light emitting elements on a circuit board and spaced apart from each other, the plurality of light emitting elements configured to emit light forward, respectively; a reflective layer on a transparent substrate facing the circuit board, the reflective layer including openings at positions corresponding to the plurality of light emitting elements such that light emitted from the plurality of light emitting elements respectively passes through corresponding openings and is emitted forward, the reflective layer being configured to reflect light from the front; and a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively.

The light blocking layer may be formed in an area other than an area where the plurality of light emitting elements are provided on the circuit board.

The light blocking layer may be configured to at least partially cover side surfaces of the plurality of light emitting elements and to absorb light emitted from the side surfaces of the plurality of light emitting elements.

The reflective layer may further include a second light blocking layer on a surface facing the light blocking layer.

The display device may further include a transparent adhesive layer between the circuit board and the transparent substrate and configured to bond the circuit board and the transparent substrate.

The plurality of light emitting elements may include a blue light emitting element configured to emit blue light, a green light emitting element configured to emit green light, and a red light emitting element configured to emit red light.

The plurality of light emitting elements may be configured to emit light of a specific wavelength, where the display device further includes a color conversion layer configured to convert light of the specific wavelength into light of a different wavelength and emit the converted light.

The color conversion layer may be formed in the openings.

The transparent substrate may have a thickness equal to or less than a preset thickness such that light emitted from the plurality of light emitting elements does not reach ends of the transparent substrate in a direction in which the transparent substrate extends.

The plurality of light emitting elements may be configured to overlap the openings in plan view.

The plurality of light emitting elements may be micro light emitting diodes (LEDs).

The transparent substrate may be larger than the circuit board in plan view, where the display device further includes a plurality of the circuit boards bonded to the transparent substrate.

According to an aspect of the disclosure, a display system may include a plurality of the display devices, each including: a plurality of light emitting elements on a circuit board and spaced apart from each other, the plurality of light emitting elements configured to emit light forward, respectively; a reflective layer on a transparent substrate facing the circuit board, the reflective layer including openings at positions corresponding to the plurality of light emitting elements such that light emitted from the plurality of light emitting elements respectively passes through corresponding openings and is emitted forward, the reflective layer being configured to reflect light from the front; and a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively. The plurality of the display devices may be in a tile shape.

According to the display device of the present disclosure, a high-quality image may be displayed even when using a small and high-luminance light emitting element to provide higher display luminance and higher reflectivity.

Further, according to the display system of the present disclosure, the degree of freedom in the shape of the display plane may be enhanced.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A display device, comprising:
a plurality of light emitting elements on a circuit board and spaced apart from each other, the plurality of light emitting elements configured to emit light forward, respectively;
a reflective layer on a transparent substrate facing the circuit board, the reflective layer comprising openings at positions corresponding to the plurality of light emitting elements such that light emitted from the plurality of light emitting elements respectively passes through corresponding openings and is emitted forward, the reflective layer being configured to reflect light from the front; and
a light blocking layer between the circuit board and the transparent substrate and configured to absorb a portion of light emitted from the plurality of light emitting elements so as to prevent light emitted from the plurality of light emitting elements from reaching openings adjacent to the corresponding openings respectively.

2. The display device of claim 1, wherein the light blocking layer is formed in an area other than an area where the plurality of light emitting elements are provided on the circuit board.

3. The display device of claim 2, wherein the light blocking layer is configured to at least partially cover side surfaces of the plurality of light emitting elements and to absorb light emitted from the side surfaces of the plurality of light emitting elements.

4. The display device of claim 1, wherein the reflective layer further comprises a second light blocking layer on a surface facing the light blocking layer.

5. The display device of claim 1, further comprising a transparent adhesive layer between the circuit board and the transparent substrate and configured to bond the circuit board and the transparent substrate.

6. The display device of claim 1, wherein the plurality of light emitting elements comprise a blue light emitting element configured to emit blue light, a green light emitting element configured to emit green light, and a red light emitting element configured to emit red light.

7. The display device of claim 1, wherein the plurality of light emitting elements are configured to emit light of a specific wavelength, and
wherein the display device further comprises a color conversion layer configured to convert light of the specific wavelength into light of a different wavelength and emit the converted light.

8. The display device of claim 7, wherein the color conversion layer is formed in the openings.

9. The display device of claim 1, wherein the transparent substrate has a thickness equal to or less than a preset thickness such that light emitted from the plurality of light emitting elements does not reach ends of the transparent substrate in a direction in which the transparent substrate extends.

10. The display device of claim 1, wherein the plurality of light emitting elements are configured to overlap the openings in plan view.

11. The display device of claim 1, wherein the plurality of light emitting elements are micro light emitting diodes (LEDs).

12. The display device of claim 1, wherein the transparent substrate is larger than the circuit board in plan view, and
wherein the display device further comprises a plurality of the circuit boards bonded to the transparent substrate.

13. A display system comprising a plurality of the display devices of claim 1, wherein the plurality of the display devices, each having the transparent substrate and the circuit board of a same size, are in a tile shape.
